(19) United States
(12) Patent Application Publication
(10) Pub. No.: US 2023/0164972 A1
(43) Pub. Date: May 25, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Qiang Wan, Hefei City (CN); Kangshu Zhan, Hefei City (CN); Jun Xia, Hefei City (CN); Tao Liu, Hefei City (CN); Penghui Xu, Hefei City (CN); Sen Li, Hefei City (CN)

(21) Appl. No.: 18/150,283

(22) Filed: Jan. 5, 2023

Related U.S. Application Data
(63) Continuation of application No. PCT/CN2021/135691, filed on Dec. 6, 2021.

(30) Foreign Application Priority Data
Jul. 5, 2021 (CN) 202110758568.X

(51) Int. Cl. H10B 12/00

(52) U.S. Cl. CPC H10B 12/0387; H10B 12/09

(57) ABSTRACT

The present disclosure provides a semiconductor structure and a manufacturing method thereof. The manufacturing method of a semiconductor structure includes: providing an initial structure, where the initial structure includes a capacitive contact region and a target layer located on the capacitive contact region; forming a first bottom electrode structure in the target layer, where the first bottom electrode structure is connected to at least part of the capacitive contact region; and forming, in the target layer, a second bottom electrode structure connected to the first bottom electrode structure.

### CROSS-REFERENCE TO RELATED APPLICATIONS

The present disclosure is a continuation application of International Patent Application No. PCT/CN2021/135691, filed on Dec. 6, 2021, which claims the priority to Chinese Patent Application No. 202110758568.X, titled “SEMICONDUCTOR STRUCTURE AND MANUFACTURING METHOD THEREOF” and filed on Jul. 5, 2021. The entire contents of International Patent Application No. PCT/CN2021/135691 and Chinese Patent Application No. 202110758568.X are incorporated herein by reference.

### TECHNICAL FIELD

The present disclosure relates to, but is not limited to, a semiconductor structure and a manufacturing method thereof.

### BACKGROUND

A dynamic random access memory (DRAM) is a semiconductor memory device. The DRAM is composed of a plurality of repetitive memory cells. Each memory cell includes a capacitor structure configured to store charges. The capacitor structure affects a storage capability of the DRAM.

With the development of semiconductor technologies, a charge storage capability of the DRAM is required to be stronger, but improving the charge storage capability of the DRAM is limited by a size of the capacitor structure. How to use the remaining space of the capacitor structure to improve a charge storage capability of the capacitor structure without increasing the size of the capacitor structure is one of the technical difficulties in the art.

### SUMMARY

A first aspect of the present disclosure provides a manufacturing method of a semiconductor structure. The method includes:
providing an initial structure, where the initial structure includes a capacitive contact region and a target layer located on the capacitive contact region;
forming a first bottom electrode structure in the target layer, where the first bottom electrode structure is connected to at least part of the capacitive contact region; and
forming, in the target layer, a second bottom electrode structure connected to the first bottom electrode structure.
A second aspect of the present disclosure provides a semiconductor structure, including:
a substrate;
a capacitive contact region, located in the substrate;
a first bottom electrode structure, located on the substrate, and connected to at least part of the capacitive contact region; and
a second bottom electrode structure, connected to the first bottom electrode structure.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals represent similar elements. The accompanying drawings in the following description illustrate some rather than all of the embodiments of the present disclosure. Those skilled in the art may obtain other accompanying drawings based on these accompanying drawings without creative efforts.

FIG. 1 is a flowchart of a manufacturing method of a semiconductor structure according to an exemplary embodiment of the present disclosure;

FIG. 2 is a flowchart of a manufacturing method of a semiconductor structure according to an exemplary embodiment of the present disclosure;

FIG. 3 is a flowchart of a manufacturing method of a semiconductor structure according to an exemplary embodiment of the present disclosure;

FIG. 4 is a flowchart of a manufacturing method of a semiconductor structure according to an exemplary embodiment of the present disclosure;

FIG. 5 is a flowchart of a manufacturing method of a semiconductor structure according to an exemplary embodiment of the present disclosure;

FIG. 6 is a flowchart of a manufacturing method of a semiconductor structure according to an exemplary embodiment of the present disclosure;

FIG. 7 is a flowchart of a manufacturing method of a semiconductor structure according to an exemplary embodiment of the present disclosure;

FIG. 8 is a flowchart of a manufacturing method of a semiconductor structure according to an exemplary embodiment of the present disclosure;

FIG. 9 is a flowchart of a manufacturing method of a semiconductor structure according to an exemplary embodiment of the present disclosure;

FIG. 10 is a schematic diagram of an initial structure in a manufacturing method of a semiconductor structure according to an exemplary embodiment of the present disclosure;

FIG. 11 is a schematic diagram of forming a first trench in a target layer in a manufacturing method of a semiconductor structure according to an exemplary embodiment of the present disclosure;

FIG. 12 is a schematic diagram of forming a first bottom electrode structure in a manufacturing method of a semiconductor structure according to an exemplary embodiment of the present disclosure;

FIG. 13 is a schematic diagram of forming a first sacrificial layer in a manufacturing method of a semiconductor structure according to an exemplary embodiment of the present disclosure;

FIG. 14 is a schematic diagram of forming a second trench in a manufacturing method of a semiconductor structure according to an exemplary embodiment of the present disclosure;

FIG. 15 is a schematic diagram of depositing a second bottom electrode structure in a manufacturing method of a semiconductor structure according to an exemplary embodiment of the present disclosure;

FIG. 16 is a schematic diagram of forming a second bottom electrode structure in a manufacturing method of a semiconductor structure according to an exemplary embodiment of the present disclosure;

FIG. 17 is a schematic diagram of removing a first sacrificial layer in a manufacturing method of a semiconductor structure according to an exemplary embodiment of the present disclosure;

FIG. 18 is a schematic diagram of forming a photoresist mask in a manufacturing method of a semiconductor structure according to an exemplary embodiment of the present disclosure;

FIG. 19 is a schematic diagram of removing part of a support layer c in a manufacturing method of a semiconductor structure according to an exemplary embodiment of the present disclosure;

FIG. 20 is a schematic diagram of removing a dielectric layer b in a manufacturing method of a semiconductor structure according to an exemplary embodiment of the present disclosure;

FIG. 21 is a schematic diagram of removing part of a support layer b in a manufacturing method of a semiconductor structure according to an exemplary embodiment of the present disclosure;

FIG. 22 is a schematic diagram of removing a dielectric layer a in a manufacturing method of a semiconductor structure according to an exemplary embodiment of the present disclosure;

FIG. 23 is a schematic diagram of forming a dielectric structure in a manufacturing method of a semiconductor structure according to an exemplary embodiment of the present disclosure;

FIG. 24 is a schematic diagram of forming a top electrode structure in a manufacturing method of a semiconductor structure according to an exemplary embodiment of the present disclosure;

FIG. 25 is a schematic diagram of forming a top electrode filling structure in a manufacturing method of a semiconductor structure according to an exemplary embodiment of the present disclosure;

FIG. 26 is a schematic diagram of an initial structure in a manufacturing method of a semiconductor structure according to an exemplary embodiment of the present disclosure;

FIG. 27 is a schematic diagram of forming a third trench in a target layer in a manufacturing method of a semiconductor structure according to an exemplary embodiment of the present disclosure;

FIG. 28 is a schematic diagram of depositing a first bottom electrode structure in a manufacturing method of a semiconductor structure according to an exemplary embodiment of the present disclosure;

FIG. 29 is a schematic diagram of forming a first bottom electrode structure in a manufacturing method of a semiconductor structure according to an exemplary embodiment of the present disclosure;

FIG. 30 is a schematic diagram of forming a third mask layer in a manufacturing method of a semiconductor structure according to an exemplary embodiment of the present disclosure;

FIG. 31 is a schematic diagram of forming a fourth trench in a manufacturing method of a semiconductor structure according to an exemplary embodiment of the present disclosure;

FIG. 32 is a schematic diagram of forming a second bottom electrode structure in a manufacturing method of a semiconductor structure according to an exemplary embodiment of the present disclosure;

FIG. 33 is a schematic diagram of removing a second dielectric layer in a manufacturing method of a semiconductor structure according to an exemplary embodiment of the present disclosure;

FIG. 34 is a schematic diagram of forming a dielectric structure in a manufacturing method of a semiconductor structure according to an exemplary embodiment of the present disclosure;

FIG. 35 is a schematic diagram of forming a top electrode structure in a manufacturing method of a semiconductor structure according to an exemplary embodiment of the present disclosure;

FIG. 36 is a schematic diagram of forming a top electrode filling structure in a manufacturing method of a semiconductor structure according to an exemplary embodiment of the present disclosure;

FIG. 37 is a schematic diagram of forming a trench in a manufacturing method of a semiconductor structure according to an exemplary comparison embodiment of the present disclosure;

FIG. 38 is a schematic diagram of forming a capacitor hole in a manufacturing method of a semiconductor structure according to an exemplary comparison embodiment of the present disclosure;

FIG. 39 is a schematic diagram of forming a bottom electrode structure in a manufacturing method of a semiconductor structure according to an exemplary comparison embodiment of the present disclosure;

FIG. 40 is a schematic diagram of forming a dielectric structure in a manufacturing method of a semiconductor structure according to an exemplary comparison embodiment of the present disclosure; and

FIG. 41 is a schematic diagram of forming a top electrode structure in a manufacturing method of a semiconductor structure according to an exemplary comparison embodiment of the present disclosure.

Reference numerals:
01. Initial structure; 100. Substrate; 200. Capacitive contact region; 300. Target layer; 310. Dielectric layer; 310a. Dielectric layer a; 310b. Dielectric layer b; 320. Support layer; 320a. Support layer a; 320b. Support layer b; 320c. Support layer c; 11. First bottom electrode structure; 12. Second bottom electrode structure; 121. Annular portion; 122. Cylindrical portion; 001. First trench; 400. First mask layer; 410. First opening; 011. Capacitor hole; 002. Second trench; 500. First sacrificial layer; 30. Photoresist mask; 31. First dielectric layer; 32. Second dielectric layer; 13. Dielectric structure; 14. Top electrode structure; 003. Third trench; 600. Second mask layer; 610. Second opening; 004. fourth trench; 700. Third mask layer; and 710. Third opening; and
01′. Initial structure; 100′. Substrate; 200′. Capacitive contact region; 300′. Target layer; 400′. Mask layer; 410′. First opening; 011′. Capacitor hole; 001′. Trench; 11′. Bottom electrode structure; 13′. Dielectric structure; and 14′. Top electrode structure.

### DETAILED DESCRIPTION

The technical solutions in the embodiments of the present disclosure are described below clearly and completely with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

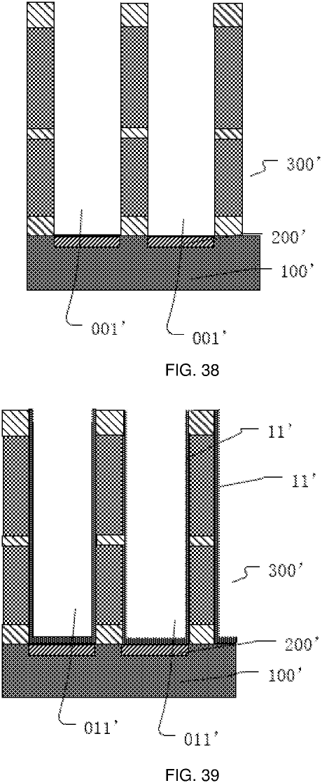

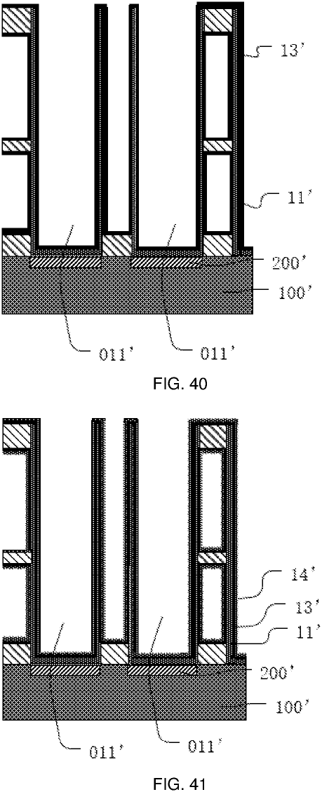

As shown in FIG. 37 to FIG. 41, currently, a manufacturing method of a capacitor structure includes: first, providing an initial structure 01′, where the initial structure 01′ includes a capacitive contact region 200′ and a target layer 300′ located on the capacitive contact region 200′, forming a mask layer 400′ on a top surface of the target layer 300′, where the mask layer 400′ has a first opening 410′, etching the target layer 300′ according to the mask layer 400′ to form a trench 001′, and forming a bottom electrode structure 11′ in the trench 001′, where the bottom electrode structure 11′ is provided to enclose a capacitor hole 011′ on the substrate 100′, and a bottom portion of the bottom electrode structure 11′ is connected to a partial structure of the capacitive contact region 200′; and then, depositing a dielectric structure 13′ on the bottom electrode structure 11′, where the dielectric structure 13′ covers an outer surface of the bottom electrode structure 11′, and depositing a top electrode structure 14′ on the dielectric structure 13′, where the top electrode structure 14′ covers an outer surface of the dielectric structure 13′.

A structure of a capacitor structure obtained by using the manufacturing method of a capacitor structure is shown in FIG. 41. An area of the outer surface exposed by the bottom electrode structure 11′ is small, and a deposition area of the dielectric structure 13′ is small. Consequently, a charge storage capability of the capacitor structure is limited.

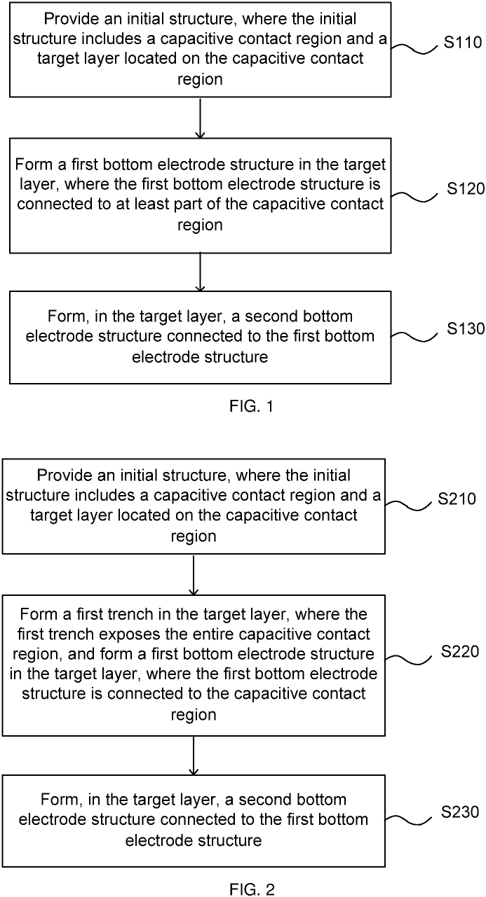

In view of this, an embodiment of the present disclosure provides a manufacturing method of a semiconductor structure. FIG. 1 is a schematic flowchart of a manufacturing method of a semiconductor structure according to an embodiment of the present disclosure. As shown in FIG. 1, the method in this embodiment includes the following steps.

S110: Provide an initial structure, where the initial structure includes a capacitive contact region and a target layer located on the capacitive contact region.

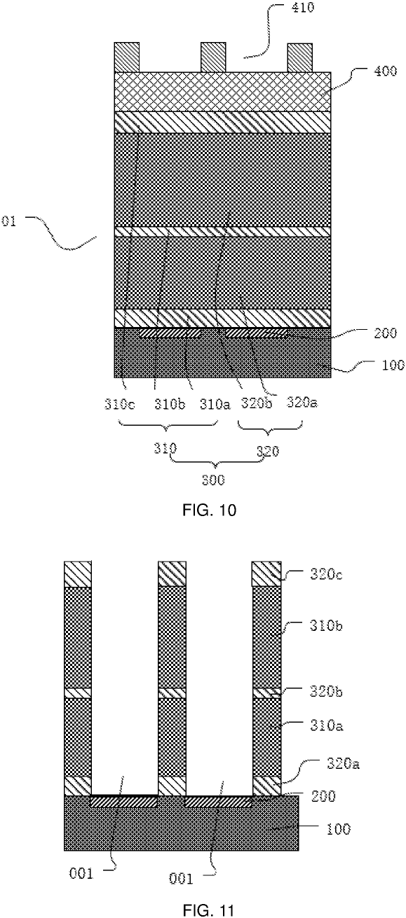

As shown in FIG. 10, a provided initial structure 01 includes a substrate 100 and a target layer 300 provided on the substrate 100, and a capacitive contact region 200 is provided in the substrate 100, where part of a bottom surface of the target layer 300 is in contact with the capacitive contact region 200. In this embodiment, the target layer 300 includes a support layer 320 and a dielectric layer 310 that are alternately provided on the substrate 100. A semiconductor structure is formed by etching the target layer 300. A specific quantity of stacked layers and a stacked height of the support layer 320 and the dielectric layer 310 that are of the target layer 300 are specified according to a height of a to be-formed semiconductor structure.

The dielectric layer 310 is made of a material including silicon oxide or boro-phospho-silicate glass (BPSG), and the material of the dielectric layer 310 may be doped with boron or phosphorus. The support layer 320 is made of a material including any one or two of silicon nitride, silicon oxynitride, and silicon carbide.

S120: Form a first bottom electrode structure in the target layer, where the first bottom electrode structure is connected to at least part of the capacitive contact region.

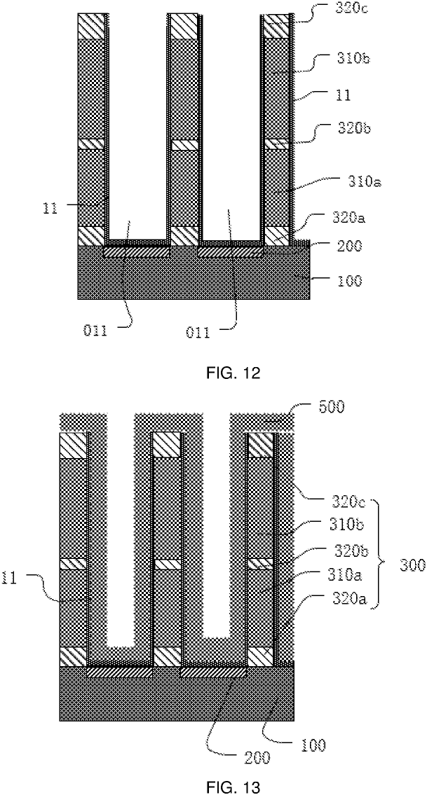

As shown in FIG. 12 and FIG. 25, the first bottom electrode structure 11 is provided in the target layer 300, and the first bottom electrode structure 11 is connected to the entire or part of the capacitive contact region 200. The first bottom electrode structure 11 may be deposited by using an atomic layer deposition (ALD) process. The first bottom electrode structure 11 is made of a material including a compound formed by one or two of metal nitride and metal silicide, such as titanium nitride, titanium silicide, nickel silicide, titanium silicon nitride (TiSiₓN_{y}). In this embodiment, the material of the first bottom electrode structure 11 is titanium nitride.

S130: Form, in the target layer, a second bottom electrode structure connected to the first bottom electrode structure.

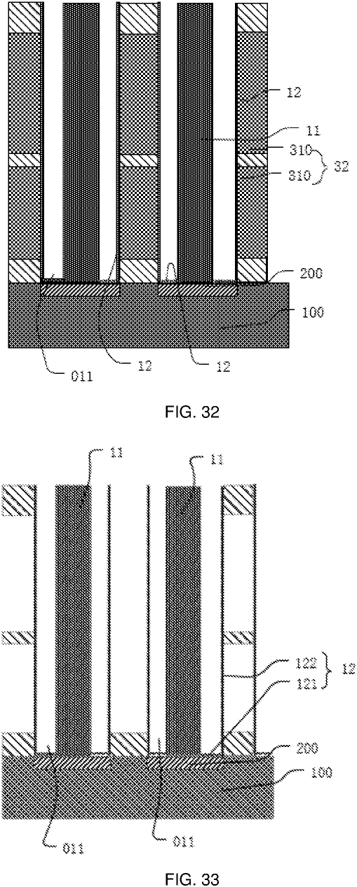

As shown in FIG. 17 and FIG. 32, a bottom surface of a second bottom electrode structure 12 is connected to the first bottom electrode structure 11, and the remaining part of the second bottom electrode structure 12 is separated from the first bottom electrode structure 11. In this embodiment, the second bottom electrode structure 12 may be deposited in the target layer 300 by using the ALD process. The second bottom electrode structure is made of a material including a compound formed by one or two of metal nitride and metal silicide, such as titanium nitride, titanium silicide, nickel silicide, and TiSiₓN_{y}. In this embodiment, the first bottom electrode structure 11 and the second bottom electrode structure 12 are made of a same material, which is titanium nitride.

Referring to FIG. 17 and FIG. 32, bottom electrodes, of a semiconductor structure, obtained through manufacturing in an embodiment of the present disclosure include the first bottom electrode structure 11 and the second bottom electrode structure 12, and the first bottom electrode structure 11 is connected to part of the second bottom electrode structure 12. On the basis that space occupied by the bottom electrode in the semiconductor structure remains unchanged, an area of an outer surface exposed by the first bottom electrode structure 11 and the second bottom electrode structure 12 is larger, such that the capacitor structure has better charge storage performance.

According to the manufacturing method of a semiconductor structure in this embodiment of the present disclosure, a manufacturing process of the semiconductor structure is improved, such that the remaining space of the semiconductor structure is fully used, and a proportion of the bottom electrode structure is increased, thereby improving a charge storage capability of the semiconductor structure.

In an embodiment of the present disclosure, a manufacturing method of a semiconductor structure is provided. FIG. 2 is a flowchart of a manufacturing method of a semiconductor structure according to this embodiment. As shown in FIG. 2, the method in this embodiment includes the following steps.

S210: Provide an initial structure, where the initial structure includes a capacitive contact region and a target layer located on the capacitive contact region.

S220: Form a first trench in the target layer, where the first trench exposes the entire capacitive contact region, and form a first bottom electrode structure in the target layer, where the first bottom electrode structure is connected to the capacitive contact region.

S230: Form, in the target layer, a second bottom electrode structure connected to the first bottom electrode structure.

Step S210 and step S230 of this embodiment are implemented in the same manner as step S110 and step S130 of the foregoing embodiment and are not described in detail again herein.

As shown in FIG. 11, in step S220, a first trench 001 is formed in a target layer 300, where the first trench 001 exposes the entire capacitive contact region 200. Referring to FIG. 12, the first bottom electrode structure 11 is formed in the first trench 001, where the first bottom electrode structure 11 is connected to the capacitive contact region 200.

As shown in FIG. 10, a first mask layer 400 is formed on the target layer 300 of the initial structure, where the first mask layer 400 includes a first opening 410, and the first opening 410 corresponds to a position of the capacitive contact region 200 on the substrate. The target layer 300 is etched according to the first mask layer 400. The target layer 300 corresponding to the first opening 410 is etched and the etching is not stopped until the capacitive contact region 200 is exposed. As shown in FIG. 11, the first trench 001 is obtained. In this embodiment, a size of the first opening 410 may be greater than or equal to a size of the capacitive contact region 200, and projection of the capacitive contact region 200 on the substrate 100 is located in a projection range of the first opening 410 on the substrate 100, such that the first trench 001 obtained through etching according to the first opening 410 exposes the entire capacitive contact region 200.

FIG. 12 shows a process of forming the first bottom electrode structure 11 in the first trench 001, where the first bottom electrode structure 11 is connected to the capacitive contact region 200. Referring to FIG. 11, the first bottom electrode structure 11 is formed on a sidewall and a bottom surface of the first trench 001, the first bottom electrode structure 11 is in contact with and connected to the capacitive contact region 200, and the first bottom electrode structure 11 encloses a capacitor hole 011. The first bottom electrode structure 11 may be deposited on the sidewall and the bottom of the first trench 001 and a top surface of the target layer 300 by using the ALD process. Then, the first bottom electrode structure 11 located on the top surface of the target layer 300 is removed by using a dry etching process, and the first bottom electrode structure 11 located on the sidewall and the bottom of the first trench 001 is retained.

In this embodiment, referring to FIG. 11 and FIG. 12, the formed first bottom electrode structure 11 covers the sidewall and the bottom surface of the first trench 001, and the first bottom electrode structure 11 encloses the capacitor hole 011, to provide space for subsequently depositing the second bottom electrode structure 12.

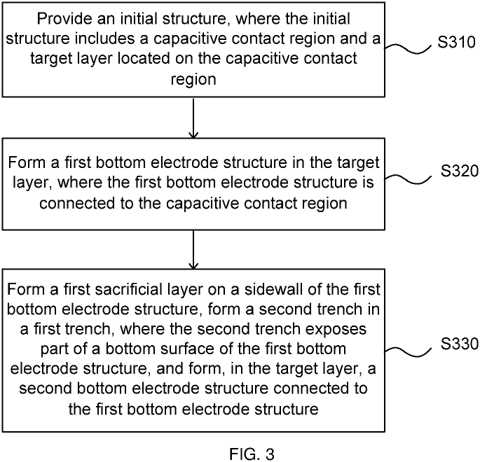

In an embodiment of the present disclosure, a manufacturing method of a semiconductor structure is provided. FIG. 3 is a flowchart of a manufacturing method of a semiconductor structure according to this embodiment. As shown in FIG. 3, the method in this embodiment includes the following steps.

S310: Provide an initial structure, where the initial structure includes a capacitive contact region and a target layer located on the capacitive contact region 200.

S320: Form a first bottom electrode structure in the target layer, where the first bottom electrode structure is connected to the capacitive contact region.

S330: Form a first sacrificial layer on a sidewall of the first bottom electrode structure, form a second trench in a first trench, where the second trench exposes part of a bottom surface of the first bottom electrode structure, and form, in the target layer, a second bottom electrode structure connected to the first bottom electrode structure.

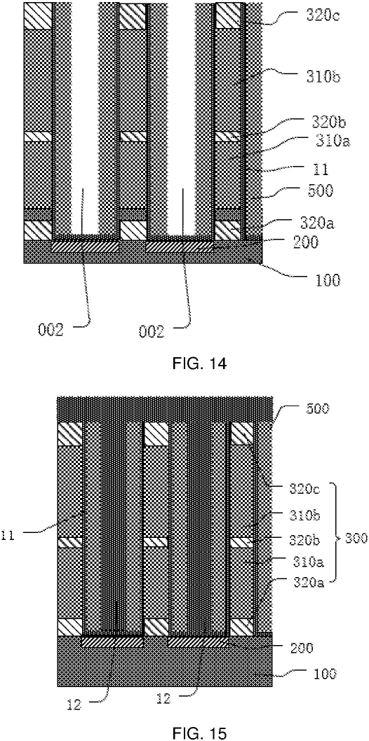

As shown in FIG. 13, referring to FIG. 12, first, a first sacrificial layer 500 is deposited in the capacitor hole 011, where the first sacrificial layer 500 covers the sidewall of the first bottom electrode structure 11, a bottom wall of the first bottom electrode structure 11, and the top surface of the target layer 300. Then, as shown in FIG. 14, the first sacrificial layer 500 covering the bottom wall of the first bottom electrode structure 11 and the top surface of the target layer 300 is removed by using an etching process, and the first sacrificial layer 500 covering the sidewall of the first bottom electrode structure 11 is retained, to form a second trench 002 in the first trench 001, where the first sacrificial layer 500 surrounds the sidewall of the first bottom electrode structure 11 to enclose a second trench 002, and the second trench 002 exposes part of a bottom surface of the first bottom electrode structure 11.

In this embodiment, referring to FIG. 13 and FIG. 14, the first sacrificial layer 500 may be deposited on the sidewall and the bottom of the first bottom electrode structure 11 and the top surface of target layer 300 by using the ALD process. When the first sacrificial layer 500 is etched, the first sacrificial layer 500 located on the top surface of the target layer 300 and the bottom wall of the first bottom electrode structure 11 may be removed by using a high selectivity ratio dry etching process, and the first sacrificial layer 500 located on the sidewall of the first trench 001 is retained. The first sacrificial layer 500 is made of a material including silicon oxide or BPSG. The material of the first sacrificial layer 500 may be doped with boron or phosphorus.

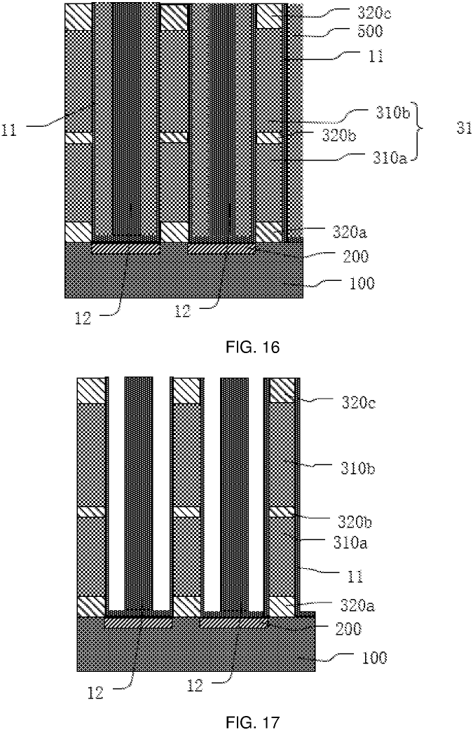

As shown in FIG. 15, referring to FIG. 14, in this embodiment, the second bottom electrode structure 12 is deposited in the second trench 002 and the top surface of the target layer 300 by using the ALD process. Then, as shown in FIG. 16, the second bottom electrode structure 12 located on the top surface of the target layer 300 is removed by using the dry etching process, and the second bottom electrode structure 12 located in the second trench 002 is retained, where the second bottom electrode structure 12 is flush with the top surface of the target layer 300. In this embodiment, the first bottom electrode structure 11 and the second bottom electrode structure 12 are made of a same material, which is titanium nitride.

In this embodiment, referring to FIG. 14 and FIG. 15, after the first bottom electrode structure 11 is formed, the first bottom electrode structure 11 covers the sidewall and the bottom surface of the first trench 001, the remaining space that is still not be used exists in the first trench 001, the second bottom electrode structure 12 continues to be deposited in the first trench 001, part of the first bottom electrode structure 11 covering the bottom wall of the first trench 001 is connected to the bottom of the second bottom electrode structure 12, and a spacing is formed between the first bottom electrode structure 11 covering the sidewall of the first trench 001 and the second bottom electrode structure 12. The second bottom electrode structure 12 fully uses the remaining space of the first bottom electrode structure 11, to increase an area of an outer surface of the bottom electrode.

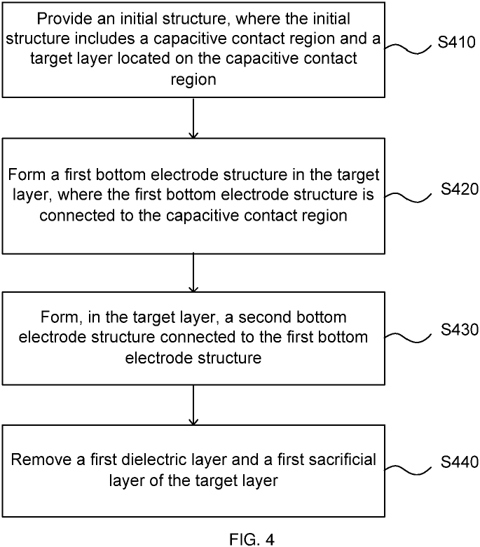

In an embodiment of the present disclosure, a manufacturing method of a semiconductor structure is provided. FIG. 4 is a flowchart of a manufacturing method of a semiconductor structure according to this embodiment. As shown in FIG. 4, the method in this embodiment includes the following steps.

S410: Provide an initial structure, where the initial structure includes a capacitive contact region and a target layer located on the capacitive contact region.

S420: Form a first bottom electrode structure in the target layer, where the first bottom electrode structure is connected to the capacitive contact region.

S430: Form, in the target layer, a second bottom electrode structure connected to the first bottom electrode structure.

S440: Simultaneously remove a first dielectric layer and a first sacrificial layer of the target layer.

In this embodiment, step S410 to step S430 of this embodiment are implemented in the same manner as step S310 to step S330 of the foregoing embodiment and are not described in detail again herein.

A direction shown in FIG. 15 is used as a reference direction, and the target layer 300 in this embodiment includes a support layer a 320a, a dielectric layer a 310a, a support layer b 320b, a dielectric layer b 310b, and a support layer c 320c that are sequentially stacked from bottom to top. As shown in FIG. 16, after the second bottom electrode structure 12 is formed, the remaining part of the dielectric layer a 310a and the dielectric layer b 310b constitute a first dielectric layer 31.

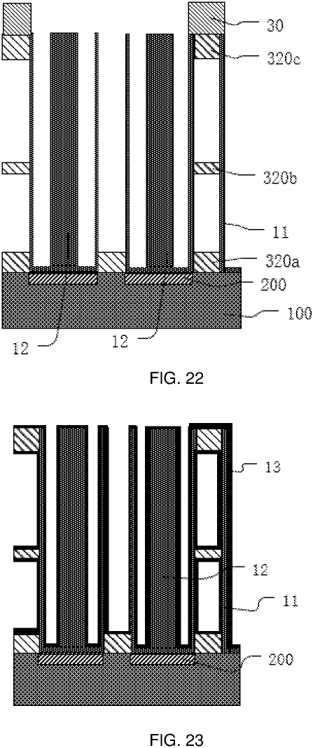

As shown in FIG. 22, referring to FIG. 16, the first sacrificial layer 500 and the first dielectric layer 31 are removed. In this embodiment, the entire first sacrificial layer 500 may be first removed through dry etching or wet etching, and then the dielectric layer b 310b and the dielectric layer a 310a are removed.

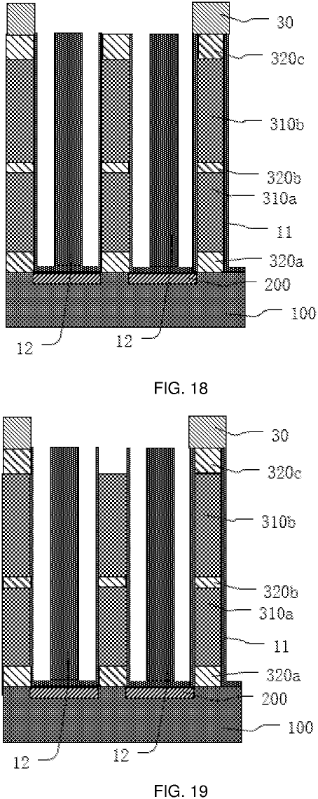

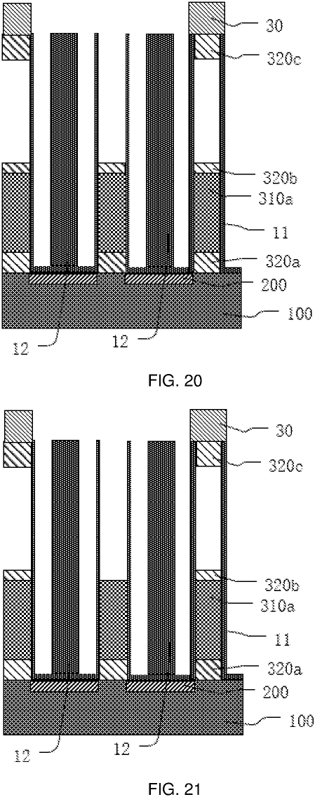

As shown in FIG. 17 to FIG. 22, the process of removing the first dielectric layer 31 includes: forming a photoresist mask 30 on an upper surface of the support layer c 320c, where the photoresist mask 30 shields at least an edge region of the support layer c 320c, removing, through etching, the support layer c 320c not shielded by the photoresist mask 30, to expose the dielectric layer b 310b, removing, through dry or wet etching, the dielectric layer b 310b, to expose the support layer b 320b, etching the support layer b 320b by still using the photoresist mask 30 as a shield, to expose the dielectric layer a 310a, and removing, through dry or wet etching, the dielectric layer a 310a.

In this embodiment, the first dielectric layer 31 and the first sacrificial layer 500 are removed to prepare for subsequent manufacturing of the semiconductor structure.

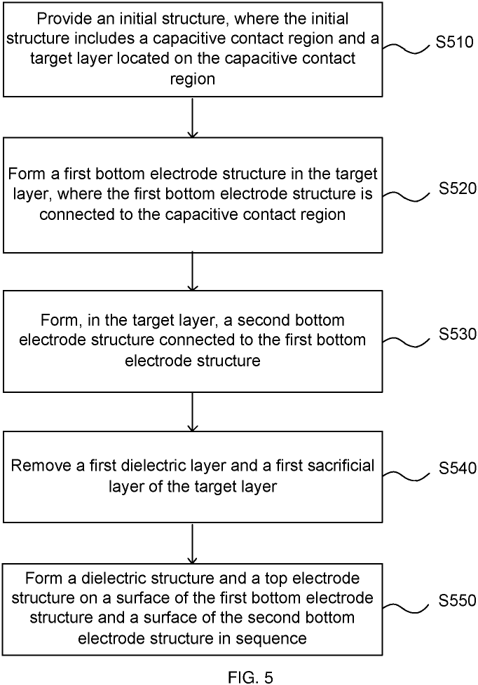

In an embodiment of the present disclosure, a manufacturing method of a semiconductor structure is provided. FIG. 5 is a flowchart of a manufacturing method of a semiconductor structure according to this embodiment. As shown in FIG. 5, the method in this embodiment includes the following steps.

S510: Provide an initial structure, where the initial structure includes a capacitive contact region and a target layer located on the capacitive contact region.

S520: Form a first bottom electrode structure in the target layer, where the first bottom electrode structure is connected to the capacitive contact region.

S530: Form, in the target layer, a second bottom electrode structure connected to the first bottom electrode structure.

S540: Remove a first dielectric layer and a first sacrificial layer of the target layer.

S550: Form a dielectric structure and a top electrode structure on a surface of the first bottom electrode structure and a surface of the second bottom electrode structure in sequence.

Step S510 to step S540 of this embodiment are implemented in the same manner as step S410 to step S440 of the foregoing embodiment and are not described in detail again herein.

As shown in FIG. 23, in step S550, a high-K material may be deposited, as a dielectric structure 13, on an outer surface of the first bottom electrode structure 11 and the second bottom electrode structure 12 by using the ALD process, where the dielectric structure 13 covers at least the outer surface of the first bottom electrode structure 11 and the second bottom electrode structure 12.

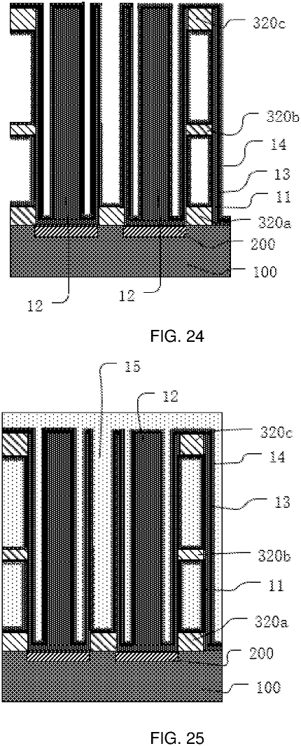

As shown in FIG. 24, a top electrode structure 14 may be deposited on an outer surface of the dielectric structure 13 by using the ALD process, where the top electrode structure 14 includes a compound formed by one or two of metal nitride and metal silicide, such as titanium nitride, titanium silicide, nickel silicide, or TiSiₓN_{y}.

In this embodiment, as shown in FIG. 25, after the top electrode structure 14 is deposited on the outer surface of the dielectric structure 13, a top electrode filling structure 15 is formed, where the top electrode filling structure 15 covers an outer surface of the top electrode structure 14, and fills up a gap of the top electrode structure 14, where the top electrode filling structure 15 is made of a material including boron doped with germanium silicon.

In the semiconductor structure of this embodiment, referring to FIG. 25, the dielectric structure 13 and the top electrode structure 14 are sequentially deposited on the first bottom electrode structure 11 and the second bottom electrode structure 12, and encapsulation is performed to obtain a capacitor structure. In this embodiment, a deposition area of the dielectric structure 13 of the semiconductor structure is larger. This further increases a charge storage capability of the capacitor structure.

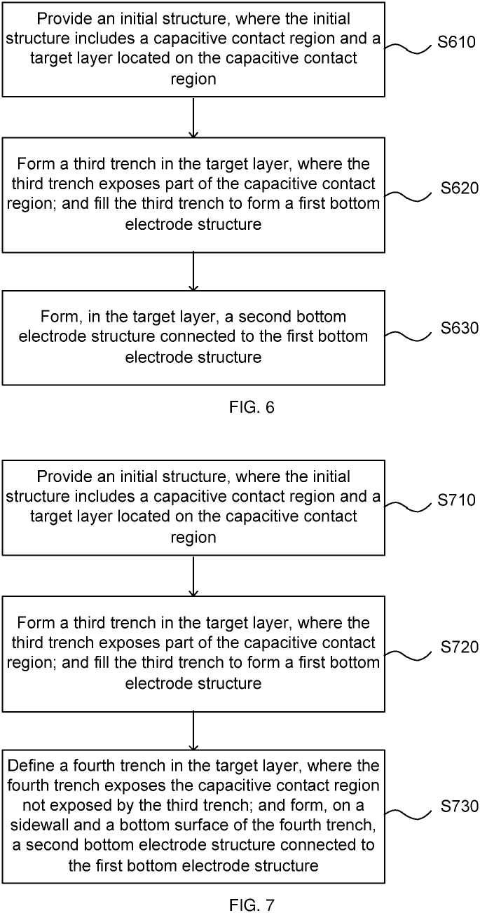

In an embodiment of the present disclosure, a manufacturing method of a semiconductor structure is provided. FIG. 6 is a flowchart of a manufacturing method of a semiconductor structure according to this embodiment. As shown in FIG. 6, the method in this embodiment includes the following steps.

S610: Provide an initial structure, where the initial structure includes a capacitive contact region and a target layer located on the capacitive contact region.

The initial structure includes a substrate, the capacitive contact region is provided in the substrate, the target layer is provided on the substrate, and part of a bottom surface of the target layer is in contact with the capacitive contact region.

S620: Form a third trench in the target layer, where the third trench exposes part of the capacitive contact region; and fill the third trench to form a first bottom electrode structure.

S630: Form, in the target layer, a second bottom electrode structure connected to the first bottom electrode structure.

Step S610 and step S630 of this embodiment are implemented in the same manner as step S110 and step S130 of the foregoing embodiment and are not described in detail again herein.

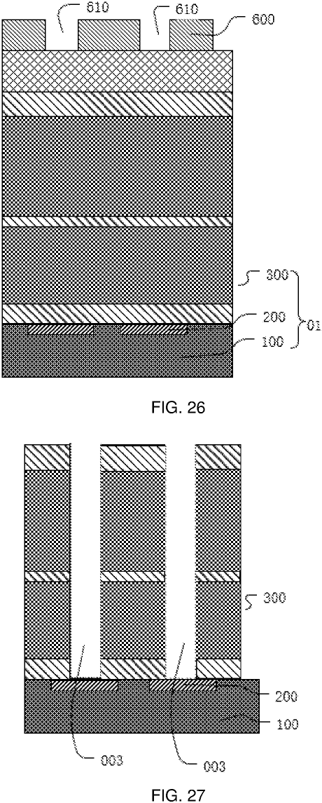

As shown in FIG. 27, referring to FIG. 26, in an implementation process of step S620 in this embodiment, a third trench 003 is formed in the target layer 300, where the third trench 003 exposes part of a capacitive contact region 200. As shown in FIG. 26, a second mask layer 600 is formed on the target layer 300, where the second mask layer 600 forms a second opening 610, and the second opening 610 corresponds to a position of the capacitive contact region 200 in the substrate 100. The target layer 300 is etched according to the second opening 610 of the second mask layer 600 and the etching is not stopped until the capacitive contact region 200 is exposed, to obtain the third trench 003. A size of the second opening 610 is less than a size of the capacitive contact region 200, and projection of the second opening 610 on the substrate 100 is located in a projection range of the capacitive contact region 200 in the substrate 100. The third trench 003 obtained through etching according to the second opening 610 exposes a central region of the capacitive contact region 200, and an edge region of the capacitive contact region 200 is still covered by the target layer 300.

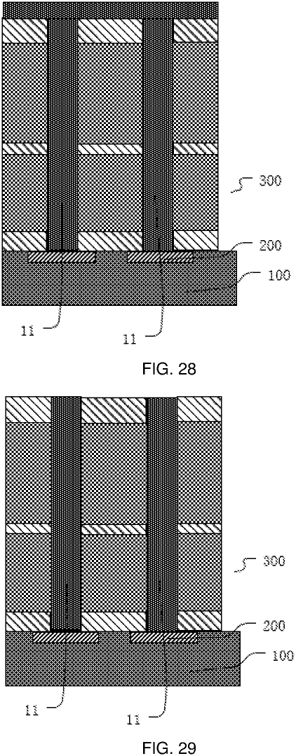

As shown in FIG. 28 and FIG. 29, in step S630 of this embodiment, referring to FIG. 27, filling the third trench 003 to form the first bottom electrode structure 11 includes: depositing the first bottom electrode structure 11, where the third trench 003 is filled with the first bottom electrode structure 11 and the first bottom electrode structure 11 covers a top surface of the target layer 300, and removing, through dry etching, the first bottom electrode structure 11 covering the top surface of the target layer 300, where the first bottom electrode structure 11 retained in the third trench 003 is flush with the top surface of the target layer 300.

According to the manufacturing method of a semiconductor structure in this embodiment of the present disclosure, a manufacturing process of the semiconductor structure is improved, such that the remaining space of the semiconductor structure is fully used, and a proportion of the bottom electrode structure is increased, thereby improving a charge storage capability of the semiconductor structure.

In an embodiment of the present disclosure, a manufacturing method of a semiconductor structure is provided. FIG. 7 is a flowchart of a manufacturing method of a semiconductor structure according to this embodiment. As shown in FIG. 7, the method in this embodiment includes the following steps.

S710: Provide an initial structure, where the initial structure includes a capacitive contact region and a target layer located on the capacitive contact region.

The initial structure includes a substrate, the capacitive contact region is provided in the substrate, the target layer is provided on the substrate, and part of a bottom surface of the target layer is in contact with the capacitive contact region.

S720: Form a third trench in the target layer, where the third trench exposes part of the capacitive contact region; and fill the third trench to form a first bottom electrode structure.

S730: Define a fourth trench in the target layer, where the fourth trench exposes the capacitive contact region not exposed by the third trench; and form, on a sidewall and a bottom surface of the fourth trench, a second bottom electrode structure connected to the first bottom electrode structure.

Step S710 and step S730 of this embodiment are implemented in the same manner as step S610 and step S630 of the foregoing embodiment and are not described in detail again herein.

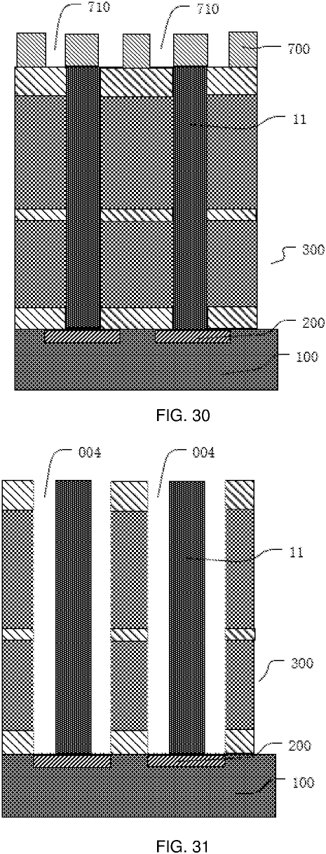

As shown in FIG. 30, referring to FIG. 29, a third mask layer 700 is formed on the target layer 300, where the third mask layer 700 covers the first bottom electrode structure 11 and part of the target layer 300, and the third mask layer 700 forms a third opening 710 surrounding the first bottom electrode structure 11 on a surface of the target layer 300; and etching the target layer 300 according to the third mask layer 700, and removing the target layer 300 corresponding to the third opening 710, to expose the capacitive contact region 200 not exposed by the third trench 003, and as shown in FIG. 31, form a fourth trench 004.

As shown in FIG. 32, referring to FIG. 31, a second bottom electrode material is deposited in the fourth trench 004, where the second bottom electrode material covers a bottom wall and a sidewall of the fourth trench 004 and a top surface of the target layer 300, and removing, through dry etching, the second bottom electrode material on the top surface of the target layer 300, to retain, as a second bottom electrode structure 12, the second bottom electrode material covering the bottom wall and the sidewall of the fourth trench 004.

Referring to FIG. 32, in this embodiment, the second bottom electrode structure 12 is formed at the periphery of the first bottom electrode structure 11, and the second bottom electrode structure 12 surrounds the first bottom electrode structure 11 and is in partial contact with the first bottom electrode structure 11, such that the space of the semiconductor structure is fully used, a proportion of the bottom electrode is increased, and further an area of a surface exposed by the bottom electrode structure is increased.

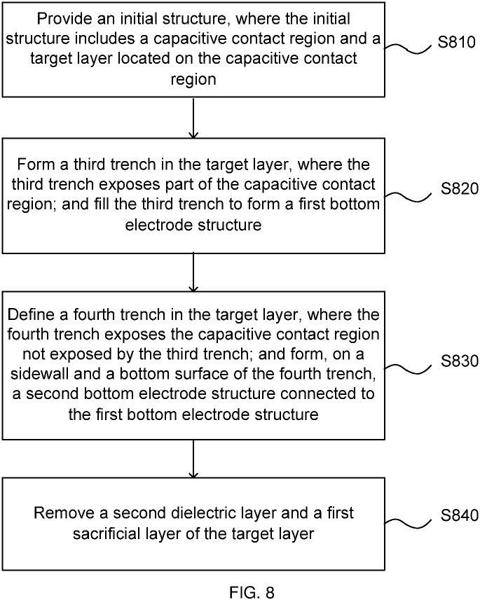

In an embodiment of the present disclosure, a manufacturing method of a semiconductor structure is provided. FIG. 8 is a flowchart of a manufacturing method of a semiconductor structure according to this embodiment. As shown in FIG. 8, the method in this embodiment includes the following steps.

S810: Provide an initial structure, where the initial structure includes a capacitive contact region and a target layer located on the capacitive contact region.

The initial structure includes a substrate, the capacitive contact region is provided in the substrate, the target layer is provided on the substrate, part of a bottom surface of the target layer is in contact with the capacitive contact region, and the target layer includes a dielectric layer.

S820: Form a third trench in the target layer, where the third trench exposes part of the capacitive contact region; and fill the third trench to form a first bottom electrode structure.

S830: Define a fourth trench in the target layer, where the fourth trench exposes the capacitive contact region not exposed by the third trench; and form, on a sidewall and a bottom surface of the fourth trench, a second bottom electrode structure connected to the first bottom electrode structure.

S840: Remove a second dielectric layer of the target layer.

Step S810 to step S830 of this embodiment are implemented in the same manner as step S710 to step S730 of the foregoing embodiment and are not described in detail again herein.

As shown in FIG. 32, after the second bottom electrode structure 12 is formed, the remaining part of the dielectric layer 310 forms a second dielectric layer 32. In this embodiment, referring to FIG. 33, after the second bottom electrode structure 12 is formed, the first sacrificial layer 500 (refer to FIG. 16) and the entire second dielectric layer 32 in the substrate 100 are simultaneously removed.

In this embodiment, the second dielectric layer 32 is removed to prepare for subsequent manufacturing of the semiconductor structure.

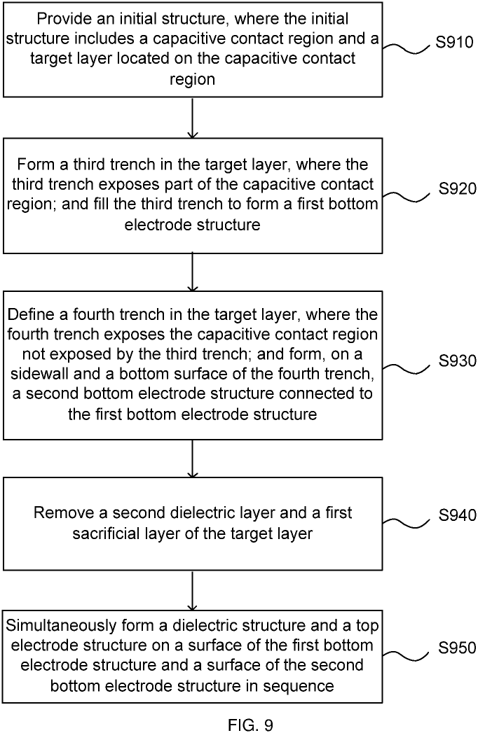

In an embodiment of the present disclosure, a manufacturing method of a semiconductor structure is provided. FIG. 9 is a schematic flowchart of a manufacturing method of a semiconductor structure according to this embodiment. As shown in FIG. 9, the method in this embodiment includes the following steps.

S910: Provide an initial structure, where the initial structure includes a capacitive contact region and a target layer located on the capacitive contact region. The initial structure includes a substrate, the capacitive contact region is provided in the substrate, the target layer is provided on the substrate, and part of a bottom surface of the target layer is in contact with the capacitive contact region.

S920: Form a third trench in the target layer, where the third trench exposes part of the capacitive contact region; and fill the third trench to form a first bottom electrode structure.

S930: Define a fourth trench in the target layer, where the fourth trench exposes the capacitive contact region not exposed by the third trench; and form, on a sidewall and a bottom surface of the fourth trench, a second bottom electrode structure connected to the first bottom electrode structure.

S940: Remove a second dielectric layer of the target layer.

S950: Simultaneously form a dielectric structure and a top electrode structure on a surface of the first bottom electrode structure and a surface of the second bottom electrode structure in sequence.

In this embodiment, step S910 to step 940 are the same as step S810 to step S840 of the foregoing embodiment.

Step S910 to step S940 of this embodiment are implemented in the same manner as step S810 to step S840 of the foregoing embodiment and are not described in detail again herein.

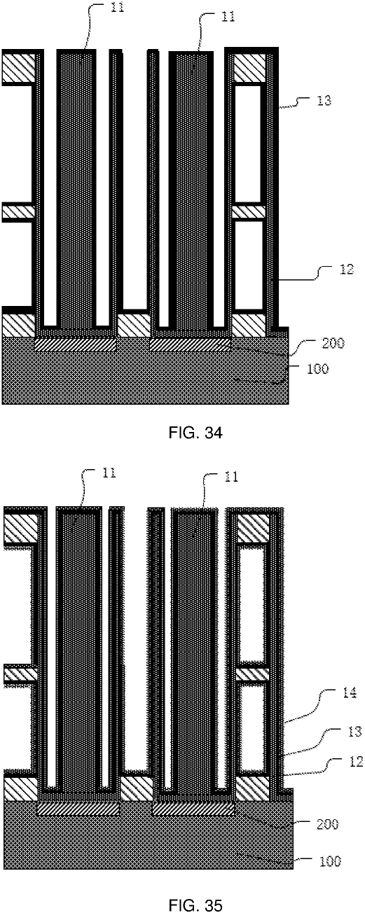

As shown in FIG. 34, a high-K material is deposited, as a dielectric structure 13, on the semiconductor structure, where the dielectric structure 13 covers at least an outer surface of the first bottom electrode structure 11 and an outer surface of the second bottom electrode structure 12. As shown in FIG. 35, a top electrode structure 14 is deposited, where the top electrode structure 14 covers an outer surface of the dielectric structure 13.

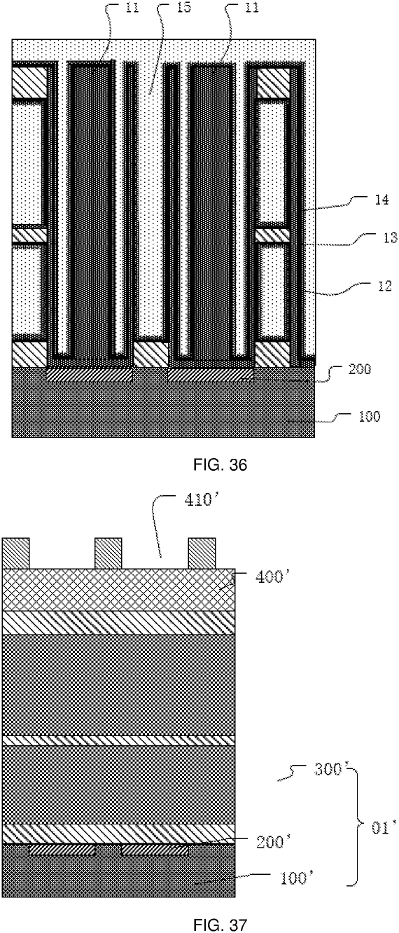

As shown in FIG. 36, in this embodiment, after the top electrode structure 14 is deposited on the outer surface of the dielectric structure 13, a top electrode filling structure 15 is formed, where the top electrode filling structure 15 covers an outer surface of the top electrode structure 14, and fills up a gap of the top electrode structure 14, where the top electrode filling structure 15 is made of a material including boron doped with germanium silicon.

An embodiment of the present disclosure provides a semiconductor structure, as shown in FIG. 22 and FIG. 33, including: a substrate 100, a capacitive contact region 200 located in the substrate 100, a first bottom electrode structure 11 located on the substrate 100, and a second bottom electrode structure 12 connected to the first bottom electrode structure 11, where the first bottom electrode structure 11 is connected to at least part of the capacitive contact region 200.

In the semiconductor structure of this embodiment, on the basis that a size and a volume of the semiconductor structure remain unchanged, the second bottom electrode structure 12 surrounds the first bottom electrode structure 11, to increase an area of a surface exposed by the bottom electrode of the semiconductor structure, such that the space of the semiconductor structure is fully used, thereby improving a charge storage capability of the capacitor.

In an embodiment of the present disclosure, as shown in FIG. 22, the semiconductor structure includes: a substrate 100, a capacitive contact region 200 located on the substrate 100, a first bottom electrode structure 11 located on the substrate 100, and a second bottom electrode structure 12 connected to the first bottom electrode structure 11, where the first bottom electrode structure 11 is provided on the capacitive contact region 200 and connected to the capacitive contact region 200; and the second bottom electrode structure 12 is provided on the first bottom electrode structure 11 and connected to the first bottom electrode structure 11.

Referring to FIG. 12 and FIG. 22, the first bottom electrode structure 11 encloses a capacitor hole 011, where the second bottom electrode structure 12 is provided in the capacitor hole 011, and a bottom wall of the second bottom electrode structure 12 is connected to part of a bottom wall of the capacitor hole 011.

As shown in FIG. 23 and FIG. 24, the semiconductor structure further includes a dielectric structure 13 covering a surface of the first bottom electrode structure 11 and a surface of the second bottom electrode structure 12 and a top electrode structure 14 covering a surface of the dielectric structure 13.

In the semiconductor structure in this embodiment, the second bottom electrode structure 12 is additionally provided in the first bottom electrode structure 11, where the bottom wall of the second bottom electrode structure 12 is in contact with part of a bottom wall of the first bottom electrode structure 11, and a spacing is formed between a sidewall of the second bottom electrode structure 12 and a sidewall of the first bottom electrode structure 11, to increase an area of a surface exposed by the bottom electrode structure, such that the remaining space of the capacitor hole 011 is fully used, thereby improving a charge storage capability of the semiconductor structure.

In an embodiment of the present disclosure, as shown in FIG. 33, the semiconductor structure includes: a substrate 100, a capacitive contact region 200 located on the substrate 100, a first bottom electrode structure 11 located on the substrate 100, and a second bottom electrode structure 12 connected to the first bottom electrode structure 11, where the first bottom electrode structure 11 is provided on the capacitive contact region 200 and connected to part of the capacitive contact region 200, the second bottom electrode structure 12 is provided on the substrate 100 and surrounds the first bottom electrode structure 11, and the second bottom electrode structure 12 is in contact with the other part of the capacitive contact region 200.

As shown in FIG. 33, the first bottom electrode structure 11 is a columnar structure, and a bottom wall of the columnar structure is in contact with part of the capacitive contact region 200; the second bottom electrode structure 12 includes an annular portion 121 and a cylindrical portion 122 that surround the first bottom electrode structure 11, an inner ring of the annular portion 121 is connected to the bottom wall of the first bottom electrode structure 11, and an outer ring of the annular portion 121 is connected to the cylindrical portion 122.

In this embodiment, as shown in FIG. 34 and FIG. 35, the semiconductor structure further includes: a dielectric structure 13, where the dielectric structure 13 covers a surface of the first bottom electrode structure 11 and a surface of the second bottom electrode structure 12; and a top electrode structure 14, where the top electrode structure 14 covers a surface of the dielectric structure 13.

In this embodiment, referring to FIG. 33, the second bottom electrode structure 12 includes an annular portion 121 and a cylindrical portion 122 that surround the first bottom electrode structure 11, an inner ring of the annular portion 121 is connected to a bottom wall of the first bottom electrode structure 11, an outer ring of the annular portion 121 is connected to the cylindrical portion 122, the cylindrical portion 122 surrounds the first bottom electrode structure 11 and is not in contact with the first bottom electrode structure 11, and an annular space is formed between the cylindrical portion 122 and the first bottom electrode structure 11. On the basis that a size and a volume of the semiconductor structure remain unchanged, the second bottom electrode structure 12 surrounds the outside of the first bottom electrode structure 11, to increase an area of a surface exposed by the bottom electrode of the semiconductor structure, such that space of the semiconductor structure is fully used, thereby improving a charge storage capability of the capacitor.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### Industrial Applicability

According to the semiconductor structure and the manufacturing method thereof that are provided in the embodiments of the present disclosure, the first bottom electrode structure and the second bottom electrode structure are formed in the target layer, to increase an area of an outer surface of the bottom electrode, such that the remaining space of the semiconductor structure is fully used, and a proportion of the bottom electrode structure is increased, thereby improving a charge storage capability of the semiconductor structure.

1. A manufacturing method of a semiconductor structure, wherein the manufacturing method comprises:
providing an initial structure, wherein the initial structure comprises a capacitive contact region and a target layer located on the capacitive contact region;
forming a first bottom electrode structure in the target layer, wherein the first bottom electrode structure is connected to at least part of the capacitive contact region; and
forming, in the target layer, a second bottom electrode structure connected to the first bottom electrode structure.

2. The manufacturing method of a semiconductor structure according to claim 1, wherein the forming a first bottom electrode structure in the target layer comprises:
forming a first trench in the target layer, wherein the first trench exposes the capacitive contact region; and
forming, on a sidewall and a bottom surface of the first trench, the first bottom electrode structure connected to the capacitive contact region.

3. The manufacturing method of a semiconductor structure according to claim 2, wherein the forming, in the target layer, a second bottom electrode structure connected to the first bottom electrode structure comprises:
forming a first sacrificial layer on a sidewall of the first bottom electrode structure, and forming a second trench in the first trench, wherein the second trench exposes part of a bottom surface of the first bottom electrode structure; and
forming, in the second trench, the second bottom electrode structure for filling the second trench.

4. The manufacturing method of a semiconductor structure according to claim 3, wherein the target layer comprises a first dielectric layer; and after the second bottom electrode structure is formed, the method further comprises: simultaneously removing the first dielectric layer and the first sacrificial layer.

5. The manufacturing method of a semiconductor structure according to claim 1, wherein the forming a first bottom electrode structure in the target layer comprises:
forming a third trench in the target layer, wherein the third trench exposes part of the capacitive contact region; and
filling the third trench to form the first bottom electrode structure.

6. The manufacturing method of a semiconductor structure according to claim 5, wherein the forming, in the target layer, a second bottom electrode structure connected to the first bottom electrode structure comprises:
defining a fourth trench in the target layer, wherein the fourth trench exposes the capacitive contact region not exposed by the third trench; and
forming, on a sidewall and a bottom surface of the fourth trench, the second bottom electrode structure connected to the first bottom electrode structure.

7. The manufacturing method of a semiconductor structure according to claim 6, wherein the defining a fourth trench in the target layer, wherein the fourth trench exposes the capacitive contact region not exposed by the third trench comprises:
forming a mask layer, wherein the mask layer covers the first bottom electrode structure and part of the target layer, and the mask layer forms, on a surface of the target layer, an opening surrounding the first bottom electrode structure; and
removing the target layer corresponding to the opening, to expose the capacitive contact region not exposed by the third trench and form the fourth trench.

8. The manufacturing method of a semiconductor structure according to claim 7, wherein the target layer comprises a second dielectric layer; and after the second bottom electrode structure is formed, the method further comprises: removing the second dielectric layer.

9. The manufacturing method of a semiconductor structure according to claim 4, wherein after the second bottom electrode structure is formed, the method further comprises:
simultaneously forming a dielectric structure and a top electrode structure on a surface of the first bottom electrode structure and a surface of the second bottom electrode structure in sequence.

10. A semiconductor structure, wherein the semiconductor structure comprises:
a substrate;
a capacitive contact region, located in the substrate;
a first bottom electrode structure, located on the substrate, and connected to at least part of the capacitive contact region; and
a second bottom electrode structure, connected to the first bottom electrode structure.

11. The semiconductor structure according to claim 10, wherein the first bottom electrode structure is provided on the capacitive contact region and in contact with the capacitive contact region; and
the second bottom electrode structure is provided on the first bottom electrode structure and connected to the first bottom electrode structure.

12. The semiconductor structure according to claim 11, wherein the first bottom electrode structure encloses a capacitor hole; and
the second bottom electrode structure is provided in the capacitor hole, and a bottom wall of the second bottom electrode structure is connected to part of a bottom wall of the capacitor hole.

13. The semiconductor structure according to claim 10, wherein the first bottom electrode structure is provided on the capacitive contact region and in contact with part of the capacitive contact region; and
the second bottom electrode structure is provided on the substrate and surrounds the first bottom electrode structure, and the second bottom electrode structure is in contact with the other part of the capacitive contact region.

14. The semiconductor structure according to claim 13, wherein the first bottom electrode structure is a columnar structure, and a bottom wall of the columnar structure is in contact with part of the capacitive contact region; and
the second bottom electrode structure comprises an annular portion and a cylindrical portion that surround the first bottom electrode structure, an inner ring of the annular portion is connected to the bottom wall of the first bottom electrode structure, and an outer ring of the annular portion is connected to the cylindrical portion.

15. The semiconductor structure according to claim 11, wherein the semiconductor structure further comprises:
a dielectric structure, wherein the dielectric structure covers a surface of the first bottom electrode structure and a surface of the second bottom electrode structure; and
a top electrode structure, wherein the top electrode structure covers a surface of the dielectric structure.

16. The manufacturing method of a semiconductor structure according to claim 8, wherein after the second bottom electrode structure is formed, the method further comprises:
simultaneously forming a dielectric structure and a top electrode structure on a surface of the first bottom electrode structure and a surface of the second bottom electrode structure in sequence.

17. The semiconductor structure according to claim 13, wherein the semiconductor structure further comprises:
a dielectric structure, wherein the dielectric structure covers a surface of the first bottom electrode structure and a surface of the second bottom electrode structure; and
a top electrode structure, wherein the top electrode structure covers a surface of the dielectric structure.
